(19) United States
(12) Patent Application Publication
(10) Pub. No.: US 2020/0335553 A1
(43) Pub. Date: Oct. 22, 2020

(54) PHOTOELECTRIC CONVERSION DEVICE, PHOTOELECTRIC CONVERSION SYSTEM, AND MOVING BODY

(71) Applicant: CANON KABUSHIKI KAISHA, Tokyo (JP)

(72) Inventors: Tatsuhito Goden, Machida-shi (JP); Hidekazu Takahashi, Zama-shi (JP)

(21) Appl. No.: 16/841,258

(22) Filed: Apr. 6, 2020

(30) Foreign Application Priority Data
Apr. 17, 2019 (JP) 2019-078584

(51) Int. Cl. H01L 27/30; H01L 51/42; H01L 51/44; H01L 23/522; H04N 5/369

(52) U.S. Cl. CPC H01L 27/307; H01L 51/4273; H04N 5/36965; H01L 23/5223; H01L 51/441

(57) ABSTRACT

Provided is a photoelectric conversion device including: a semiconductor substrate; a photoelectric conversion layer; a first electrode, a second electrode, and a third electrode. The third electrode is arranged between the first electrode and the second electrode in a first direction. A gap between the third electrode and the first electrode or the second electrode is 0.8 times or more at least one of the first length, the second length, and the third length in the first direction.

### BACKGROUND OF THE INVENTION

### Field of the Invention

The present invention relates to a photoelectric conversion device, a photoelectric conversion system, and a moving body.

### Description of the Related Art

Japanese Patent Application Laid-Open No. 2018-207224 discloses an imaging device having a photoelectric conversion layer provided on a substrate. In Japanese Patent Application Laid-Open No. 2018-207224, a pixel has a first electrode, a second electrode, and a third electrode. The photoelectric conversion layer is provided on these electrodes. The third electrode is provided between the first electrode and the second electrode. In the pixel having such a configuration, signals used for phase difference detection are output from the first electrode and the second electrode, and a signal used for image capturing is output from the third electrode. Since the third electrode is arranged between the first electrode and the second electrode and thereby the first electrode and the second electrode are arranged away from each other, a base line having a long length can be arranged. Thus, the imaging device of Japanese Patent Application Laid-Open No. 2018-207224 can achieve high ranging accuracy.

In a photoelectric conversion device using the photoelectric conversion layer as disclosed in Japanese Patent Application Laid-Open No. 2018-207224, there is a demand for further improvement of accuracy of output signals.

### SUMMARY OF THE INVENTION

The present invention intends to provide a photoelectric conversion device, a photoelectric conversion system, and a moving body having improved accuracy of output signals.

Provided is a photoelectric conversion device including: a semiconductor substrate; a photoelectric conversion layer; a first electrode, a second electrode, and a third electrode each arranged between the photoelectric conversion layer and the semiconductor substrate; and a fourth electrode arranged so as to face the first electrode, the second electrode, and the third electrode via the photoelectric conversion layer. The third electrode is arranged between the first electrode and the second electrode in a first direction parallel to the photoelectric conversion layer. The third electrode is arranged apart from the first electrode by a first gap in the first direction. The third electrode is arranged apart from the second electrode by a second gap in the first direction. The first electrode, the second electrode, and the third electrode have a first length, a second length, and a third length, respectively, in the first direction. At least one of the first gap and the second gap is 0.8 times or more at least one of the first length, the second length, and the third length.

Further features of the present invention will become apparent from the following description of exemplary embodiments with reference to the attached drawings.

### BRIEF DESCRIPTION OF THE DRAWINGS

FIG. 1 is a block diagram illustrating a general configuration of an imaging device according to a first embodiment.

FIG. 2A and FIG. 2B are diagrams illustrating a general configuration of a pixel according to the first embodiment.

FIG. 3A and FIG. 3B are diagrams illustrating ranging.

FIG. 4A, FIG. 4B, and FIG. 4C are diagrams illustrating a relationship between a parasitic capacitance and an electrode shape.

FIG. 5 is a diagram illustrating arrangement of pixels in a pixel array according to the first embodiment.

FIG. 6 is a diagram illustrating a configuration example of a pixel circuit according to the first embodiment.

FIG. 7 is a timing chart illustrating a drive method of the pixel circuit according to the first embodiment.

FIG. 8 is a sectional view illustrating in more detail the structure of a pixel according to the first embodiment.

FIG. 9A and FIG. 9B are diagrams illustrating an arrangement example of electrodes and a MIM capacitor according to the first embodiment.

FIG. 10A and FIG. 10B are diagrams illustrating an arrangement example of electrodes and a MIM capacitor according to the first embodiment.

FIG. 11A, FIG. 11B, FIG. 11C, and FIG. 11D are diagrams illustrating an example of overlapping of electrodes and a conductive layer according to the first embodiment.

FIG. 12A, FIG. 12B, and FIG. 12C are diagrams illustrating an example of overlapping of electrodes and a conductive layer according to the first embodiment.

FIG. 13A, FIG. 13B, and FIG. 13C are diagrams illustrating an example of overlapping of electrodes and a conductive layer according to the first embodiment.

FIG. 14A, FIG. 14B, and FIG. 14C are diagrams illustrating an example of overlapping of electrodes and a conductive layer according to the first embodiment.

FIG. 15 is a diagram illustrating a modified example of the pixel circuit according to the first embodiment.

FIG. 16 is a diagram illustrating a modified example of the pixel circuit according to the first embodiment.

FIG. 17 is a block diagram illustrating a configuration example of an imaging system according to a second embodiment.

FIG. 18A and FIG. 18B are diagrams illustrating a configuration example of an imaging system and a moving body according to a third embodiment.

### DESCRIPTION OF THE EMBODIMENTS

Preferred embodiments of the present invention will now be described in detail in accordance with the accompanying drawings. The same components or corresponding components are labeled with common references throughout a plurality of drawings, and the description thereof may be omitted or simplified.

### First Embodiment

An imaging device 100 of a first embodiment of the present invention will be described. The imaging device 100 is an image sensor used for capturing an image. However, a device to which the configuration of the present embodiment is applied is not limited to the image sensor. The configuration of the present embodiment may be widely applied to a photoelectric conversion device that outputs a signal generated by photoelectrically converting an incident light. Examples of a photoelectric conversion device other than the imaging device 100 may be a ranging device, a light measuring device, or the like.

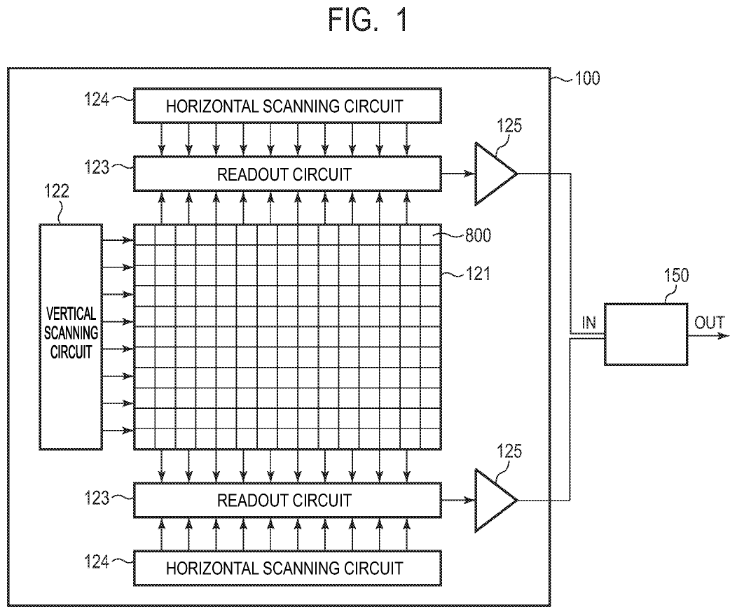

FIG. 1 is a block diagram of the imaging device 100 according to the first embodiment. The imaging device 100 has a pixel array 121, a vertical scanning circuit 122, two readout circuits 123, two horizontal scanning circuit 124, and two output amplifiers 125. The pixel array 121 has a plurality of pixels 800 arranged one-dimensionally or two-dimensionally. The arrangement of the pixel array 121 may be arrangement so as to form a plurality of rows and a plurality of columns as illustrated in FIG. 1, for example.

The vertical scanning circuit 122 may be formed of a logic circuit such as an address recorder, a shift register, or the like. The vertical scanning circuit 122 outputs control signals used for controlling signal output or the like on a row basis to the pixels 800 of the pixel array 121. The pixels 800 selected by a control signal in the pixel array 121 output pixel signals to the readout circuits 123 via output lines provided on a column basis. The readout circuit 123 may include a column amplifier circuit, a correlated double sampling (CDS) circuit, an adder circuit, or the like, for example. The readout circuit 123 performs signal processing such as amplification, addition, or the like on pixel signals input from the pixels 800 via the output lines.

The horizontal scanning circuit 124 generates control signals used for sequentially outputting signals based on pixel signals from the readout circuit 123 to the corresponding output amplifier 125. The output amplifier 125 amplifies a signal on a column selected by the horizontal scanning circuit 124 and outputs the amplified signal to the signal processing circuit 150 or the like outside the imaging device. In the following, although a configuration in which signal charges generated by the pixel 800 from an incident light are electrons is illustrated as an example, the signal charges may be holes.

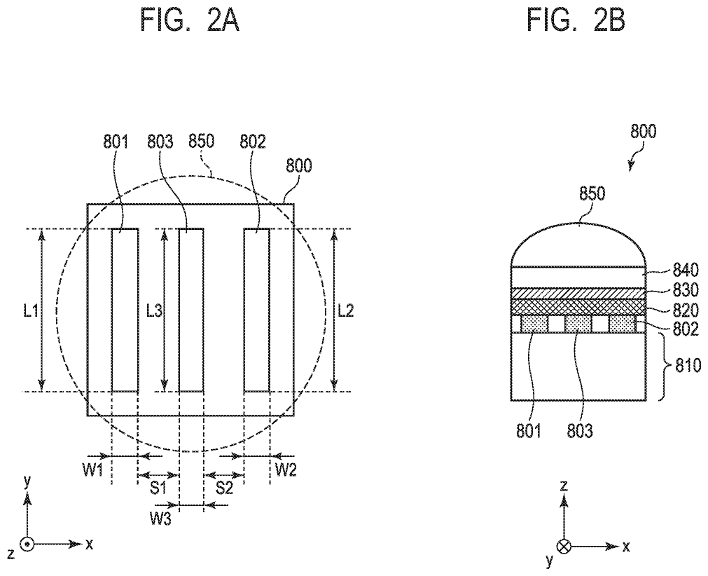

FIG. 2A is a plan view illustrating the electrode arrangement in the pixel 800 according to the present embodiment. FIG. 2B is a sectional view illustrating the general configuration of the pixel 800 according to the present embodiment. With respect to the coordinate axes represented in FIG. 2A and FIG. 2B, the x direction is a direction parallel to a light receiving face on which the pixels 800 are arranged, the y direction is a direction perpendicular to the x direction within the light receiving face, and the z direction is the normal direction of the light receiving face. An incident light enters the imaging device 100 from the +z direction.

As illustrated in FIG. 2B, the pixel 800 has a base member 810, electrodes 801, 802, and 803, a photoelectric conversion layer 820, an opposite electrode 830, a color filter 840, and a micro-lens 850. The base member 810 includes a semiconductor substrate, a conductive layer, an insulating layer, or the like in which an active element, a passive element, a wiring, or the like in the pixel 800 are formed. An example of a material forming the insulating layer may be silicon oxide, a boro-phospho silicate glass (BPSG), a phospho-silicate glass (PSG), and a borosilicate glass (BSG). Alternatively, the material of the insulating layer may be silicon nitride, silicon carbide, or the like. Further, an example of the material forming the conductive layer may be copper, aluminum, tungsten, tantalum, titanium, polysilicon, or the like.

A photoelectric conversion element formed of the electrodes 801, 802, and 803, the photoelectric conversion layer 820, and the opposite electrode 830 is provided on the base member 810. The electrode 801 (first electrode), the electrode 802 (second electrode), and the electrode 803 (third electrode) are provided on the underside (first face) of the photoelectric conversion layer 820. The electrodes 801, 802, and 803 function as the lower electrodes of the photoelectric conversion element. The electrodes 801, 802, and 803 are arranged in this order in the x direction (first direction). The opposite electrode 830 (fourth electrode) that functions as the upper electrode of the photoelectric conversion element is provided so as to cover the photoelectric conversion layer 820 on the upper side (second face) of the photoelectric conversion layer 820. In other words, the electrodes 801, 802, and 803 and the opposite electrode 830 interpose the photoelectric conversion layer 820 and are opposed to each other.

An example of the material of the electrodes 801, 802, and 803 may be a transparent conductive material such as indium tin oxide (ITO) or a nontransparent conductive material such as aluminum. The electrodes 801, 802, and 803 are electrically separate from each other so as to individually capture charges generated in different regions of the photoelectric conversion layer 820. When the electrodes 801, 802, and 803 are made of a nontransparent conductive material, the electrodes 801, 802, and 803 have a function of causing an incident light to be less likely to enter the semiconductor substrate in the base member 810.

The photoelectric conversion layer 820 includes organic compounds or quantum dots that are nano-scale semiconductor crystals that generate charges in accordance with the light amount of an incident light. A functional layer such as a charge blocking layer may be further provided above or below the photoelectric conversion layer 820. The functional layer may be arranged between the photoelectric conversion layer 820 and the electrodes 801, 802, and 803 or between the photoelectric conversion layer 820 and the opposite electrode 830. The charge blocking layer has a function of suppressing charges from being injected into the photoelectric conversion layer 820 from these electrodes.

The opposite electrode 830 is an electrode used for applying a voltage to the photoelectric conversion layer 820 and generating an electric field in the photoelectric conversion layer 820. Since the opposite electrode 830 is provided on the incident light receiving face side of the photoelectric conversion layer 820, the material of the opposite electrode 830 is the conductive material such as ITO that is transparent to the incident light.

The color filter 840 is provided on the opposite electrode 830. The color filter 840 is a primary-color based optical filter that selectively transmits red (R) light, green (G) light, or blue (B) light. Alternatively, the color filter 840 is a complementary-color based optical filter that selectively transmits cyan (C) light, magenta (M) light, or yellow (Y) light. The color filter 840 may be a white filter that transmits all the lights having wavelengths of R, G, and B or C, M, and Y or may be an IR filter that transmits an infrared ray. When the pixel 800 is used for ranging, since it is not necessary to identify color, the sensitivity is improved when a white filter is employed to the color filter 840. Note that, when there is a step between the upper faces of the color filters 840 of a plurality of pixels 800 due to presence of multiple types of the color filters 840, a planarization layer may be further provided on the color filters 840.

The micro-lens 850 is provided on the color filter 840. The micro-lens 850 is formed by using a material such as a resin. In the present embodiment, for example, a region in which one micro-lens 850 is provided can be defined as one pixel. The circle with a dashed line illustrated in FIG. 2A indicates the outer edge of the micro-lens 850.

Next, the arrangement of the electrodes 801, 802, and 803 will be described in more detail with reference to FIG. 2A. Each of the electrodes 801, 802, and 803 forms a rectangle extending in the y direction (second direction). In other words, the length W1 (first length) in the x direction of the electrode 801 is smaller than the length L1 (fourth length) in the y direction. The length W2 (second length) in the x direction of the electrode 802 is smaller than the length L2 (fifth length) in the y direction. The length W3 (third length) in the x direction of the electrode 803 is smaller than the length L3 (sixth length) in the y direction. These configurations increase the efficiency of charge collection at the electrodes 801, 802, and 803 in they direction. Note that, in the present specification, the length in the x direction of each electrode may be referred to as an electrode width.

Further, the electrode 801 and the electrode 803 are arranged apart from each other by a gap S1 (first gap) in the x direction, and the electrode 802 and the electrode 803 are arranged apart from each other by a gap S2 (second gap) in the x direction. The gap S1 and the gap S2 are even in the y direction. In other words, the rectangular electrodes 801, 802, and 803 are arranged in parallel to each other in the y direction.

The x direction is a phase difference detection direction when ranging is performed by a phase difference detection scheme in the imaging device 100 of the present embodiment. Two signals read out from the electrode 801 and the electrode 802, respectively, are used for acquisition of distance information using a phase difference. A signal read out from the electrode 803 is used as a signal used for image capturing.

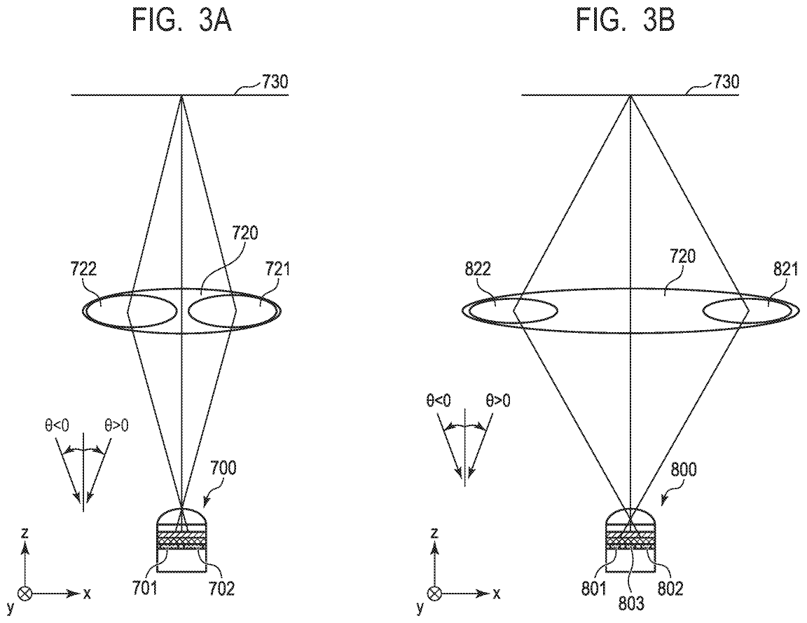

FIG. 3A and FIG. 3B are diagrams illustrating ranging using a plurality of electrodes provided below the photoelectric conversion layer. FIG. 3A illustrates an example of ranging in a pixel 700 having two electrodes 701 and 702 as a comparative example to the present embodiment. FIG. 3B illustrates an example of ranging in the pixel 800 of the present embodiment.

FIG. 3A illustrates a relationship of the pixel 700, an exit pupil 720, and an object 730. The pupil division direction corresponds to the x direction, and a light reflected by the object 730 enters the pixel 700 from the +z direction. Regions of the exit pupil 720 divided by the two electrodes 701 and 702 are defined as pupil regions 721 and 722, respectively. The light that has passed through the pupil region 721 causes charges to occur in a portion located above the electrode 701 of the photoelectric conversion layer. On the other hand, a light that has passed through the pupil region 722 causes charges to occur in a portion located above the electrode 702 of the photoelectric conversion layer. Two parallax images can be acquired from signal charges collected by the electrode 701 and signal charges collected by the electrode 702. Thereby, ranging can be performed by using the triangulation principle. As with the pixel 700, the pixel that enables both ranging and image capturing is typically configured such that the region combining the pupil region 721 and the pupil region 722 corresponding to the electrodes 701 and 702 is equal to the entirety of the exit pupil 720.

FIG. 3B illustrates an example of ranging in the pixel 800 having the electrodes 801, 802, and 803 in the present embodiment. In the present embodiment, the electrode 803 is arranged between the electrode 801 and the electrode 802. Thereby, the electrode 801 and the electrode 802 are arranged at both ends of the pixel 800. Accordingly, the distance between the center of the pupil region 821 and the center of the pupil region 822 in FIG. 3B is longer than the distance between the center of the pupil region 721 and the center of the pupil region 722 in FIG. 3A. In such a way, the pixel 800 of the present embodiment can have a longer base line length. Therefore, in the imaging device 100 of the present embodiment, the ranging accuracy is improved.

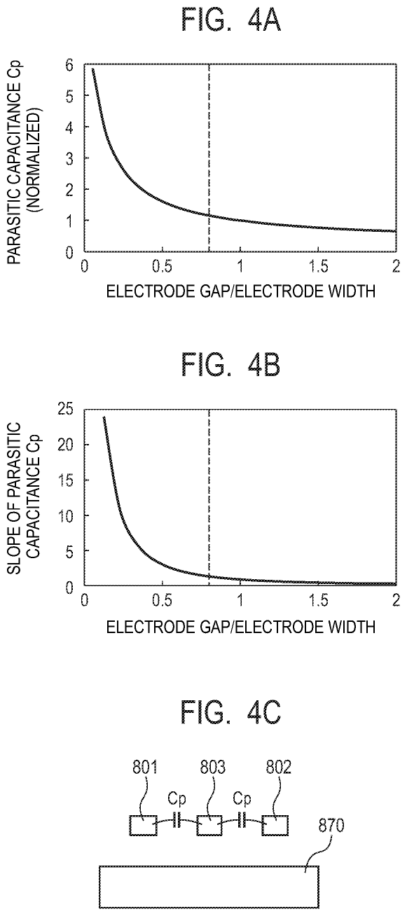

Next, the relationship between the electrode width, the electrode gap, and a parasitic capacitance Cp will be described with reference to FIG. 4A, FIG. 4B, and FIG. 4C. Further, FIG. 4C is a model of electrode arrangement in calculation of the parasitic capacitance Cp. The primary cause of the parasitic capacitance Cp lies in an electrostatic capacitance occurring between the electrode 801 and the electrode 803 or an electrostatic capacitance occurring between the electrode 802 and the electrode 803. However, since a wiring layer 870 provided below the electrodes 801, 802, and 803 also influences the parasitic capacitance Cp, the influence of the wiring layer 870 is taken into account in this model. Note that the wiring layer 870 corresponds to wirings between the electrodes 801, 802, and 803 and a metal insulator metal (MIM) capacitance within the pixel or a wiring forming a MIM capacitor, for example.

FIG. 4A is a graph illustrating a result when the relationship between the ratio of the electrode gap to the electrode width (electrode gap/electrode width) and the parasitic capacitance Cp occurring between electrodes is calculated in a condition where the pixel size is constant. The value of the parasitic capacitance Cp is normalized so that Cp=1 when the ratio of electrode gap/electrode width is 1. In such calculation of the parasitic capacitance Cp, it is assumed that the electrode widths of the electrodes 801, 802, and 803 are the same (that is, W1=W2=W3). Further, it is assumed that the electrode gap between the electrode 801 and the electrode 803 and the electrode gap between the electrodes 802 and the electrode 803 are the same (that is, S1=S2). However, even when these values are not the same, a similar tendency is resulted. FIG. 4B is a graph illustrating the relationship between the ratio of electrode gap/electrode width in the graph of FIG. 4A and the absolute value of the slope of the parasitic capacitance Cp.

As illustrated in FIG. 4A and FIG. 4B, the value and the slope of the parasitic capacitance tend to be larger in the range of the ratio of electrode gap/electrode width <1 than in the range of the ratio of electrode gap/electrode width 1. This is because of an increase in a capacitance value between electrodes due to a small electrode gap and an increase in a capacitance value between an electrode and the wiring layer 870 due to a large electrode width. An increase in the parasitic capacitance Cp added to the electrodes 801, 802, and 803 may cause an increase in kTC noise (noise occurring when charges accumulated in a photoelectric conversion element are reset). Further, this parasitic capacitance Cp may cause an increase in crosstalk between electrodes. Further, since an increase in the value and the slope of the parasitic capacitance Cp is more significant in the range of the ratio of electrode gap/electrode width <0.8, the influence of the above cause on deterioration of accuracy may also be significant.

When the electrode gap is 0.8 times or more the electrode width, since the parasitic capacitance Cp is reduced, deterioration of accuracy due to the above cause is also reduced. Therefore, according to the present embodiment, because the electrode gap is 0.8 times or more the electrode width, the imaging device 100 with improved accuracy of output signals is provided.

Further, when the electrode gap is 1 time or more the electrode width (that is, the electrode gap is larger than or equal to the electrode width), since the parasitic capacitance Cp is further reduced, deterioration of accuracy due to the above cause is further reduced. Therefore, it is more preferable that the electrode gap be one time or more the electrode width.

Further, it is more preferable that, in the x direction, the length W3 of the electrode 803 be smaller than the length W1 of the electrode 801 or the length W2 of the electrode 802. According to such a configuration, since it is possible to increase the electrode gap to reduce the parasitic capacitance Cp while sufficiently ensuring the level of signals used for phase difference detection read out from the electrode 801 and the electrode 802, an advantageous effect of improved ranging accuracy can be obtained in addition to the advantageous effect described above.

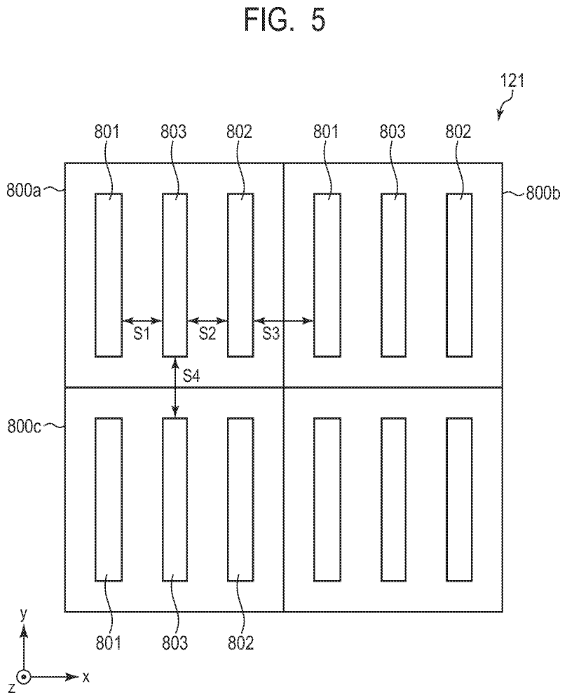

FIG. 5 is a diagram illustrating arrangement of the pixels 800 in the pixel array 121. In FIG. 5, only the pixels of two rows by two columns are depicted out of the plurality of pixels forming the pixel array 121. As illustrated in FIG. 5, pixels 800b and 800c (second pixel) are adjacent to one pixel 800a (first pixel) within the pixel array 121.

Herein, the gap between the electrode (electrode 801, 802, or 803) included in the pixel 800a and the electrode included in the pixel 800b or the pixel 800c is denoted as a gap S3 or a gap S4. In such a case, it is preferable that the gap S3 or the gap S4 be larger than or equal to the gap S1 and the gap S2. In other word, it is preferable that the electrode gap of electrodes between pixels be larger than or equal to the electrode gap of electrodes within a pixel. According to such a configuration, advantageous effects of a reduction of the parasitic capacitance Cp occurring between adjacent pixels and a reduction of crosstalk between adjacent pixels are obtained.

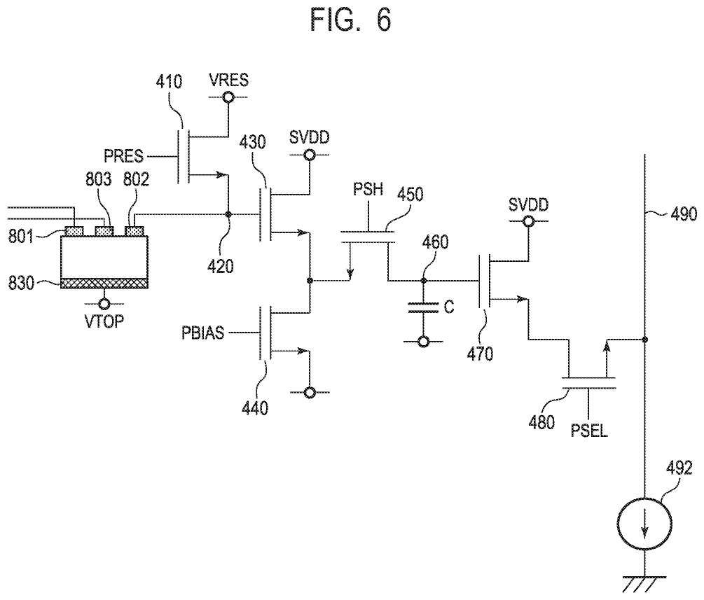

FIG. 6 is an equivalent circuit diagram illustrating a configuration example of a pixel circuit provided in each pixel. Although FIG. 6 illustrates only the pixel circuit connected to the electrode 802, the same pixel circuit may be connected to other electrodes. The pixel circuit has a reset transistor 410, amplifier transistors 430 and 470, a load transistor 440, a sampling transistor 450, a select transistor 480, and a holding capacitor C.

The opposite electrode 830 is connected to a potential line to which a potential VTOP is supplied. The electrode 802 is connected to a floating diffusion (FD) 420 that is the connection node of the source of the reset transistor 410 and the gate of the amplifier transistor 430. The drain of the reset transistor 410 is connected to a potential line to which a reset potential VRES is supplied. A control signal PRES is input to the gate of the reset transistor 410. The drain of the amplifier transistor 430 is connected to a potential line to which a reference potential SVDD is supplied.

The source of the amplifier transistor 430 is connected to the drain of the load transistor 440 and the source of the sampling transistor 450. The source of the load transistor 440 is connected to a potential line to which a ground potential is supplied. A control signal PBIAS is input to the gate of the load transistor 440. The load transistor 440 functions as a current source that drives the amplifier transistor 430.

The drain of the sampling transistor 450 is connected to a MEM 460 that is the connection node of a first terminal of the holding capacitor C and the gate of the amplifier transistor 470. A control signal PSH is input to the gate of the sampling transistor 450. A second terminal of the holding capacitor C is connected to a potential line to which a predetermined potential is supplied. This predetermined potential may be the ground potential, for example.

The drain of the amplifier transistor 470 is connected to a potential line to which the reference potential SVDD is supplied. The source of the amplifier transistor 470 is connected to the drain of the select transistor 480. A control signal PSEL is input to the gate of the select transistor 480. The source of the select transistor 480 is connected to the output line 490 to which a current source 492 is connected. The potential output to an output line 490 is input to the readout circuit 123. Note that the control signals PSEL, PBIAS, PRES, and PSH may be input from the vertical scanning circuit 122.

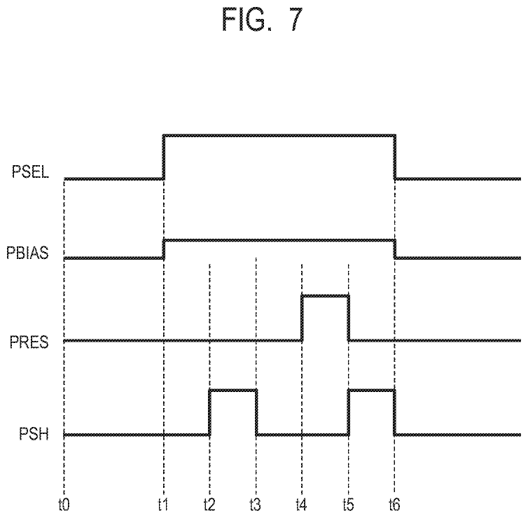

FIG. 7 is a timing chart illustrating a drive method of the pixel circuit illustrated in FIG. 6. Time t0 is any time when accumulation of charges generated by the photoelectric conversion layer 820 is already started at the FD 420. At time t0, all the control signals PSEL, PBIAS, PRES, and PSH are at a low level, and all the select transistor 480, the load transistor 440, the reset transistor 410, and the sampling transistor 450 are in the off-state.

At time t1, the control signal PSEL is controlled to a high level. Thereby, the select transistor 480 is turned on, and a potential of a noise level (N-signal) corresponding to the potential of the MEM 460 is output to the output line 490 via the amplifier transistor 470 and the select transistor 480. Further, at time t1, the control signal PBIAS is controlled to the high level. Thereby, the load transistor 440 operates as a current source. Note that the potential of the high-level control signal PBIAS is set such that the load transistor 440 operates as a current source that supplies a desired value of current.

At time t2, the control signal PSH is controlled to the high level. At the subsequent time t3, the control signal PSH is controlled to the low level. Thereby, the sampling transistor 450 is in the on-state during the period from time t2 to time t3. The potential of a level corresponding to charges accumulated in the FD 420 is transferred to the MEM 460 by the above operation. The potential of a signal level (S-signal) corresponding to the potential of the MEM 460 is then output to the output line 490.

At time t4, the control signal PRES is controlled to the high level. At the subsequent time t5, the control signal PRES is controlled to the low level. Thereby, the reset transistor 410 is in the on-state during the period from the time t4 to time t5. This operation causes the potential of the FD 420 to be a potential corresponding to the reset potential VRES.

At time t5, the control signal PSH is controlled to the high level. At the subsequent time t6, the control signal PSH is controlled to the low level. Thereby, the sampling transistor 450 is in the on-state during the period from the time t5 to time t6. The potential of a noise level corresponding to the potential of the MEM 460 is transferred to the MEM 460 by the above operation. This noise level potential is held in the holding capacitor C.

At time t6, the control signals PSEL and PBIAS are controlled to the low level. Thereby, on and after time t6, all the select transistor 480, the load transistor 440, the reset transistor 410, and the sampling transistor 450 are in the off-state. Charge accumulation is restarted by this operation. Further, during a charge accumulation period on and after time t6, the holding capacitor C holds the noise level potential.

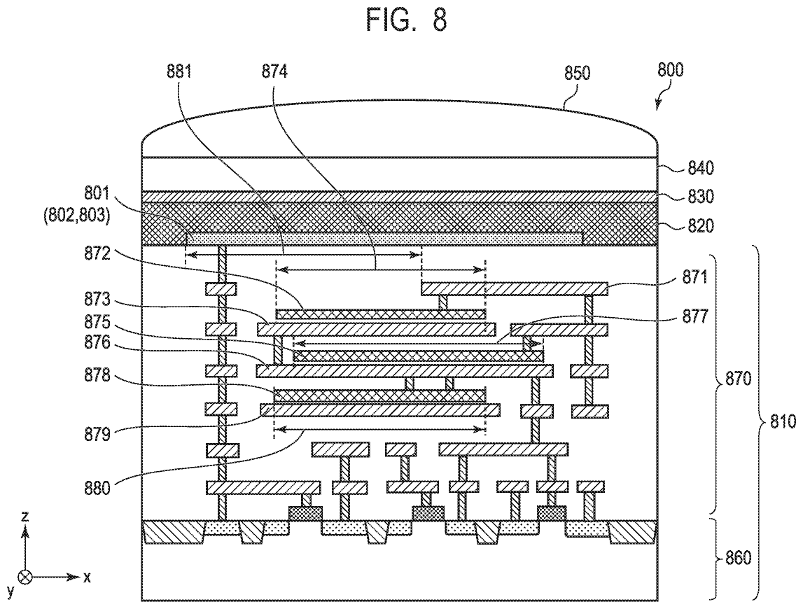

A MIM capacitor may be used for the holding capacitor C. The configuration of a MIM capacitor will be described with reference to FIG. 8. FIG. 8 is a sectional view illustrating the structure of the pixel 800 in more detail. FIG. 8 illustrates the structure of the base member 810 including the MIM capacitor in more detail out of the sectional view illustrated in FIG. 2B.

The base member 810 includes a semiconductor substrate 860 in which transistors are formed and the wiring layer 870 formed on the semiconductor substrate 860. The wiring layer 870 is structured such that a plurality of conductive layers and a plurality of insulating layers are stacked. The conductive layers are electrically connected by through holes penetrating the insulating layers. The wiring layer 870 includes a MIM capacitor formed of the conductive layer and the insulating layer. The electrode 801 (or the electrode 802 or 803), the photoelectric conversion layer 820, the opposite electrode 830, the color filter 840, and the micro-lens 850 are formed in this order above the wiring layer 870.

As illustrated in FIG. 8, a conductive layer 871 (first conductive layer) is arranged below the electrode 801 via an insulating layer. It is preferable that each of the electrodes 801, 802, and 803 have a first portion 881 that does not overlap the conductive layer 871 in plan view from the z direction. According to such a configuration, the value of the parasitic capacitance Cp occurring between each of the electrodes 801, 802, and 803 and the conductive layer 871 can be reduced, and accuracy of output signals is further improved.

A conductive layer 872 (second conductive layer) is arranged below the conductive layer 871 via an insulating layer (first insulating layer). A conductive layer 873 (third conductive layer) is arranged below the conductive layer 872 via an insulating layer (second insulating layer). The conductive layer 872 and the conductive layer 873 include a second portion 874 where both the layers are overlapped via an insulating layer (second insulating layer) in plan view from the z direction. The second portion 874 forms a part of the MIM capacitor.

A conductive layer 875 (fourth conductive layer) is arranged below the conductive layer 873 via an insulating layer (third insulating layer). A conductive layer 876 (fifth conductive layer) is arranged below the conductive layer 875 via an insulating layer (fourth insulating layer). The conductive layer 875 and the conductive layer 876 include a third portion 877 where both the layers are overlapped via an insulating layer (fourth insulating layer) in plan view from the z direction. The third portion 877 forms a part of the MIM capacitor.

A conductive layer 878 (sixth conductive layer) is arranged below the conductive layer 876 via an insulating layer (fifth insulating layer). A conductive layer 879 (seventh conductive layer) is arranged below the conductive layer 878 via an insulating layer (sixth insulating layer). The conductive layer 878 and the conductive layer 879 include a fourth portion 880 where both the layers are overlapped via an insulating layer (sixth insulating layer) in plan view from the z direction. The fourth portion 880 forms a part of the MIM capacitor.

It is preferable that the thickness of the insulating layer (second insulating layer) between the conductive layer 872 and the conductive layer 873 be smaller than the thickness of the insulating layer (first insulating layer) between the conductive layer 871 and the conductive layer 872. According to such a configuration, the capacitance value caused by the second portion 874 can be larger. To obtain a sufficiently large capacitance value, it is more preferable that the thickness of the insulating layer (second insulating layer) between the conductive layer 872 and the conductive layer 873 be less than or equal to 40 nm.

It is preferable that the thickness of the insulating layer (fourth insulating layer) between the conductive layer 875 and the conductive layer 876 be smaller than the thickness of the insulating layer (third insulating layer) between the conductive layer 873 and the conductive layer 875. According to such a configuration, the capacitance value caused by the third portion 877 can be larger. To obtain a sufficiently large capacitance value, it is more preferable that the thickness of the insulating layer (fourth insulating layer) between the conductive layer 875 and the conductive layer 876 be less than or equal to 40 nm.

It is preferable that the thickness of the insulating layer (sixth insulating layer) between the conductive layer 878 and the conductive layer 879 be smaller than the thickness of the insulating layer (fifth insulating layer) between the conductive layer 878 and the conductive layer 876. According to such a configuration, the capacitance value caused by the fourth portion 880 can be larger. To obtain a sufficiently large capacitance value, it is more preferable that the thickness of the insulating layer (sixth insulating layer) between the conductive layer 878 and the conductive layer 879 be less than or equal to 40 nm.

Note that the MIM capacitor forming the holding capacitor C is configured to include at least one of the second portion 874, the third portion 877, and the fourth portion 880, and it is not essential that electrodes are overlapped in three separate portions. Further, another conductive layer may be arranged below the conductive layer 879 to increase the number of portions where conductive layers are overlapped and further increase the capacitance value.

It is preferable that the shape of at least one of the conductive layers 871, 872, 873, 875, 876, 878, and 879 be different from the shape of another of these conductive layers in plan view. In such a case, the plurality of conductive layers are structured to be at least partially offset and overlapped with respect to each other in plan view. Therefore, these conductive layers block light that has transmitted to the base member 810 without being absorbed in the photoelectric conversion layer 820 and thereby can cause light to be less likely to enter transistors inside the semiconductor substrate 860. Accordingly, a malfunction due to a characteristic shift of a transistor due to an incident light may be reduced. Further, since light that has transmitted through the photoelectric conversion layer 820 can be reflected by the above conductive layers to return to the photoelectric conversion layer 820, the light receiving sensitivity may be improved.

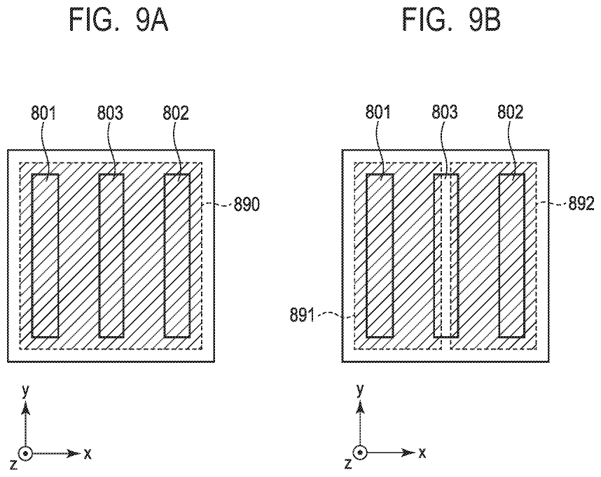

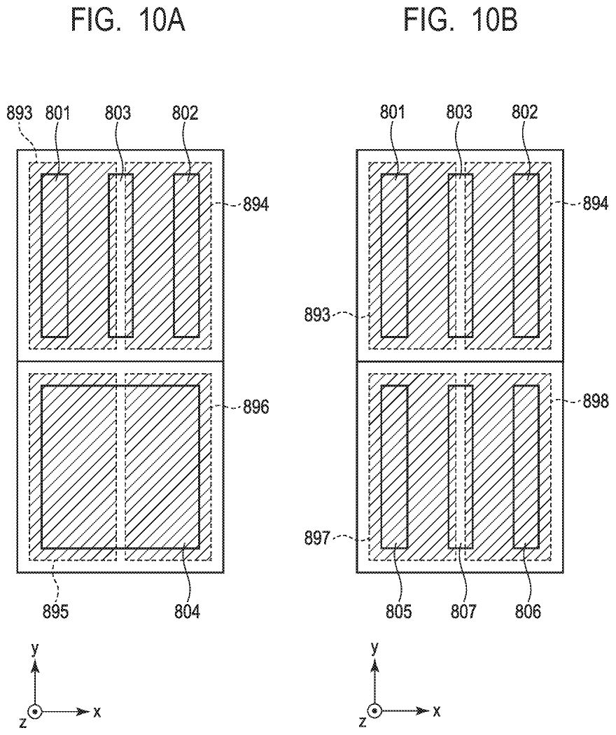

The positional relationship between the electrodes provided in the photoelectric conversion layer 820 and the MIM capacitor will be described in more detail with several examples. FIG. 9A, FIG. 9B, FIG. 10A, and FIG. 10B are perspective top views illustrating examples of the positional relationship between the electrodes 801, 802, and 803 and the MIM capacitor. Each of MIM capacitors 890, 891, and 892 in FIG. 9A and FIG. 9B indicates a portion where two conductive layers forming a MIM capacitor are overlapped.

FIG. 9A is a diagram illustrating a first arrangement example. In the first arrangement example, at least a part of the MIM capacitor 890 overlaps the gap between the electrode 801 and the electrode 803 and the gap between the electrode 802 and the electrode 803 in plan view. In such a configuration, an incident light that has passed between the electrodes is reflected by the conductive layer forming the MIM capacitor 890. Therefore, for the same reason as described above, a malfunction due to a characteristic shift of a transistor due to an incident light may be reduced. Further, the light receiving sensitivity may be improved.

FIG. 9B is a diagram illustrating a second arrangement example. In the second arrangement example, at least a part of the MIM capacitor 891 overlaps the gap between the electrode 801 and the electrode 803, and at least a part of the MIM capacitor 892 overlaps the gap between the electrode 802 and the electrode 803 in plan view. Also in such a configuration, the same advantageous effects as those in the first arrangement example can be obtained.

FIG. 10A is a diagram illustrating a third arrangement example. In the third arrangement example, a pixel having the three electrodes 801, 802, and 803 electrically separated from each other as illustrated in FIG. 2A and a pixel having one electrode 804 are adjacent to each other. FIG. 10A illustrates four MIM capacitors 893, 894, 895, and 896. The MIM capacitor 893 is the holding capacitor C provided in a pixel circuit connected to the electrode 801. The MIM capacitor 894 is the holding capacitor C provided in a pixel circuit connected to the electrode 802. The MIM capacitor 895 is the holding capacitor C provided in a pixel circuit connected to the electrode 803. The MIM capacitor 896 is the holding capacitor C provided in a pixel circuit connected to the electrode 804.

In the third arrangement example, at least a part of the MIM capacitor 893 overlaps the gap between the electrode 801 and the electrode 803, and at least a part of the MIM capacitor 894 overlaps the gap between the electrode 802 and the electrode 803 in plan view. Further, the MIM capacitors 895 and 896 are arranged below the electrode 804. Also in such a configuration, the same advantageous effects as those in the first arrangement example can be obtained.

FIG. 10B is a diagram illustrating a fourth arrangement example. In the fourth arrangement example, a pixel having the three electrodes 801, 802, and 803 electrically separated from each other as illustrated in FIG. 2A and a pixel having electrodes 805, 806, and 807 electrically shared in the wiring layer 870 are adjacent to each other. FIG. 10B illustrates four MIM capacitors 893, 894, 897, and 898. Since the MIM capacitors 893 and 894 are arranged in the same manner as the third arrangement example, the description thereof will be omitted. The MIM capacitor 897 is the holding capacitor C provided in a pixel circuit connected to the electrode 803. The MIM capacitor 898 is the holding capacitor C provided in a pixel circuit connected commonly to the electrodes 805, 806, and 807.

In the fourth arrangement example, at least a part of the MIM capacitor 897 overlaps the gap between the electrode 805 and the electrode 807, and at least a part of the MIM capacitor 898 overlaps the gap between the electrode 806 and the electrode 807 in plan view. Also in such a configuration, the same advantageous effects as those in the first arrangement example can be obtained.

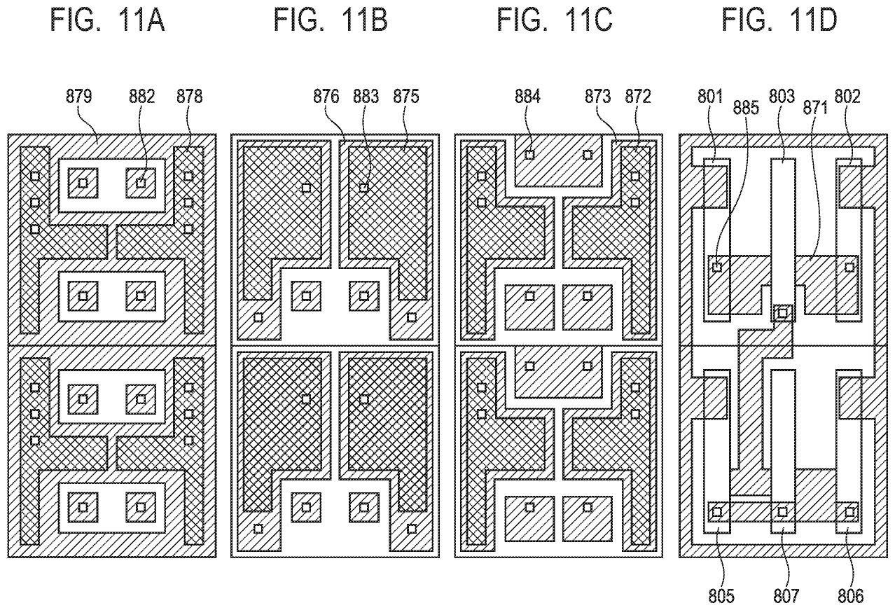

FIG. 11A to FIG. 11D are plan views of the conductive layers and the electrodes in the fourth arrangement example illustrated in FIG. 10B. FIG. 11A is a diagram illustrating the conductive layers 878 and 879 and through holes 882. Each of the through holes 882 is electrically connected between each of the conductive layers 878 and 879 and the conductive layer 876. FIG. 11B is a diagram illustrating the conductive layers 875 and 876 and through holes 883. Each of the through holes 883 is electrically connected between each of the conductive layers 875 and 876 and the conductive layer 873.

FIG. 11C is a diagram illustrating the conductive layers 873 and 872 and through holes 884. Each of the through holes 884 is electrically connected between each of the conductive layers 873 and 872 and the conductive layer 871. FIG. 11D is a diagram illustrating the electrodes 801, 802, 803, 805, 806, and 807, the conductive layer 871, and the through hole 885. Each of the through holes 885 is electrically connected between the conductive layer 871 and each of the electrodes 801, 802, 803, 805, 806, and 807.

Each region of the conductive layer 878 of FIG. 11A, the conductive layer 875 of FIG. 11B, and the conductive layer 872 of FIG. 11C corresponds to a region in which a MIM capacitor is formed. The conductive layer 879 is arranged so as to contain (that is, under-wraps) the conductive layer 878 in plan view. The conductive layer 876 is arranged so as to contain the conductive layer 875 in plan view. The conductive layer 873 is arranged so as to contain the conductive layer 872 in plan view. With such positional relationships in which one of the conductive layers contains the other conductive layer, variation in a MIM capacitor due to displacement or the like in manufacturing can be reduced.

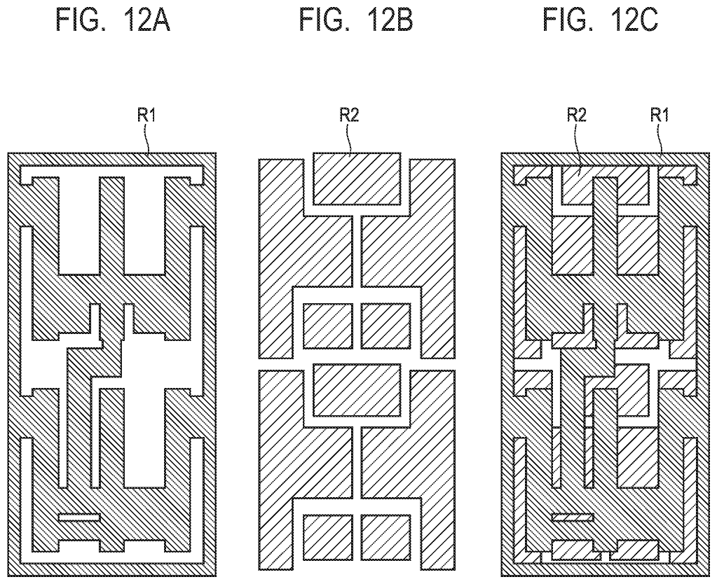

FIG. 12A to FIG. 14C are diagrams illustrating examples of overlapping of electrodes and a conductive layer in the arrangement examples illustrated in FIG. 11A to FIG. 11D. FIG. 12A illustrates a portion in which the conductive layer 871 and the electrodes 801, 802, 803, 805, 806, and 807 are arranged in plan view as a region R1. FIG. 12B illustrates a portion in which the conductive layers 872 and 873 are arranged in plan view as a region R2. FIG. 12C illustrates a plan view in which FIG. 12A is stacked on FIG. 12B. As is understood from FIG. 12C, the region of the stacked region R1 and region R2 partially includes openings. Therefore, a part of the region forming a pixel is not covered by only the region R1 and the region R2.

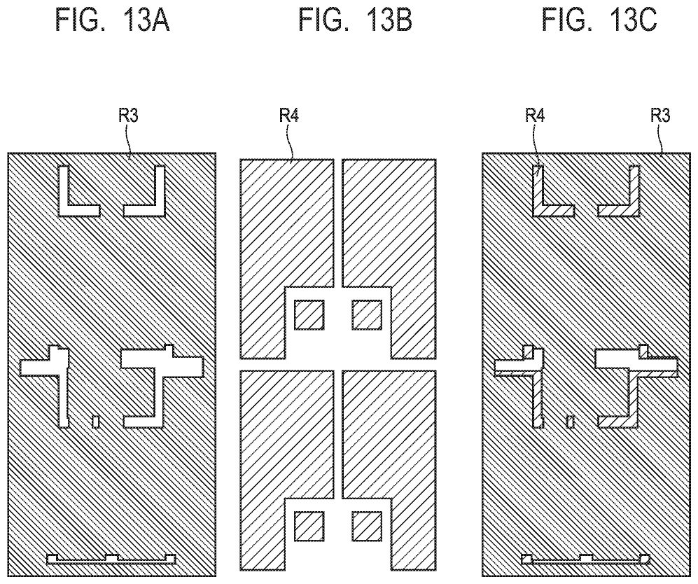

FIG. 13A illustrates a portion in which the conductive layers 871, 872, and 873 and the electrodes 801, 802, 803, 805, 806, and 807 are arranged in plan view as a region R3. FIG. 13B illustrates a portion in which the conductive layers 875 and 876 are arranged in plan view as a region R4. FIG. 13C illustrates a plan view in which FIG. 13A is stacked on FIG. 13B. As is understood from FIG. 13C, the region of the stacked region R3 and region R4 also partially includes openings, though the openings are reduced compared to the example of FIG. 12C. Therefore, a part of the region forming a pixel is not covered by even the region R3 and the region R4.

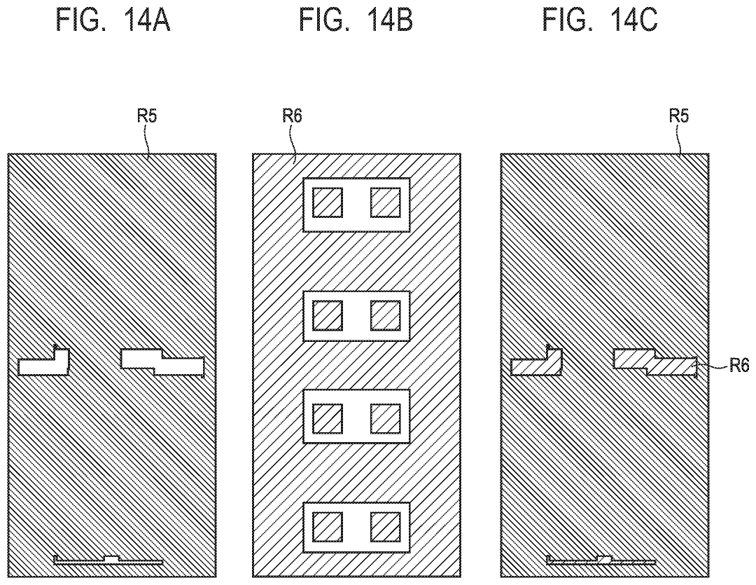

FIG. 14A illustrates a portion in which the conductive layers 871, 872, 873, 875, and 876 and the electrodes 801, 802, 803, 805, 806, and 807 are arranged in plan view as a region R5. FIG. 14B illustrates a portion in which the conductive layer 878 and the conductive layer 879 are arranged as a region R6. FIG. 14C illustrates a plan view in which FIG. 14A is stacked on FIG. 14B. As is understood from FIG. 14C, the whole region forming a pixel is covered.

As described above, in the fourth arrangement example, each gap occurring between the electrodes 801, 802, 803, 805, 806, and 807 is covered by any of the conductive layers 871, 872, 873, 875, 876, 878, and 879 in plan view. Accordingly, a malfunction due to a characteristic shift of a transistor due to an incident light may be reduced. Further, the light receiving sensitivity may be improved.

Note that, to cover the gap between electrodes, it is not essential to provide all the conductive layers 871, 872, 873, 875, 876, 878, and 879. For example, only the conductive layers 871, 872, and 873 may be provided, or only the conductive layers 871, 872, 873, 874, and 875 may be provided. With at least one conductive layer being provided below the gap between electrodes, the advantageous effects described above can be obtained.

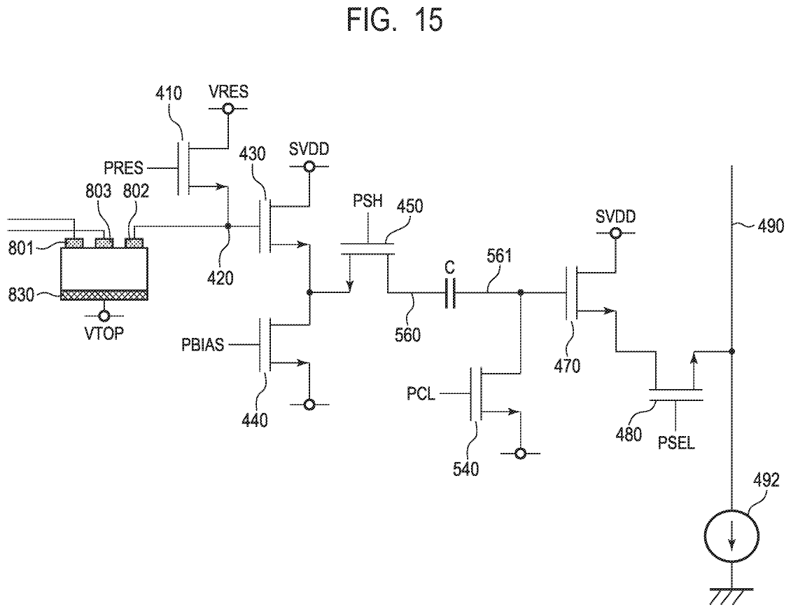

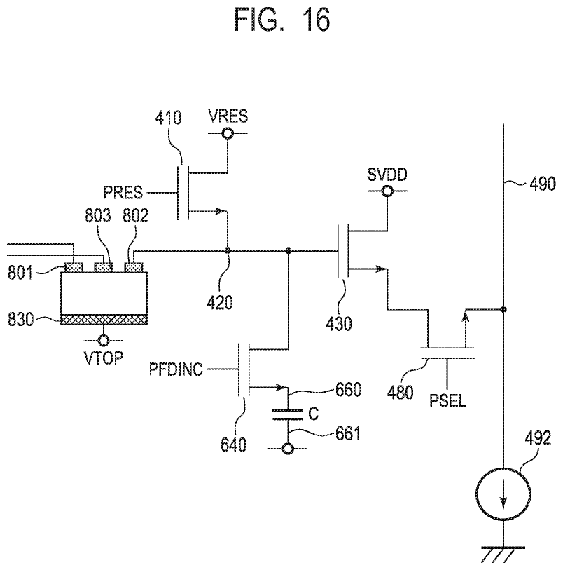

The pixel circuit illustrating in FIG. 6 is one example, and a pixel circuit is not limited thereto. Modified examples of a pixel circuit will be described with reference to FIG. 15 and FIG. 16. Note that, in the description of the modified examples of FIG. 15 and FIG. 16, description duplicated with that of the pixel circuit of FIG. 6 may be omitted or simplified.

FIG. 15 is an equivalent circuit diagram illustrating a first modified example of a pixel circuit. The pixel circuit of FIG. 15 differs from the pixel circuit of FIG. 6 in that a switch transistor 540 is further provided and that the connection of the holding capacitor C is changed to a series connection.

The drain of the sampling transistor 450 is connected to a node 560 that is a first terminal of the holding capacitor C. A second terminal of the holding capacitor C is connected to a node 561 that is a connection node of the drain of the switch transistor 540 and the gate of the amplifier transistor 470. The source of the switch transistor 540 is connected to a potential line that supplies a predetermined potential. A control signal PCL is input to the gate of the switch transistor 540. Note that the control signal PCL may be input from the vertical scanning circuit 122.

The pixel circuit of the first modified example can apply a clamp voltage to the node 561 by turning on the switch transistor 540 and thus can perform a CDS operation by using the voltage held in the holding capacitor C. More specifically, when a potential at a noise level (N-signal) that is in a state where the FD 420 is reset is applied to the node 560, the voltage corresponding to the N-signal is clamped in the holding capacitor C when a clamp voltage is applied to the node 561. Then, when a potential of at a signal level (S-signal) is applied to the node 560, a signal corresponding to the voltage change of the S-signal and the N-signal is output to the output line 490. Therefore, the pixel circuit of the first modified example can perform a CDS process.

FIG. 16 is an equivalent circuit diagram illustrating a second modified example of a pixel circuit. The pixel circuit of FIG. 16 differs from the pixel circuit of FIG. 6 in that a switch transistor 640 is further provided and that the configuration of the holding capacitor C is changed to a configuration in which the holding capacitor C may be connected to the FD 420 via the switch transistor 640. Further, in the pixel circuit of FIG. 16, the load transistor 440 and the sampling transistor 450 are omitted.

The drain of the switch transistor 640 is connected to the FD 420. The source of the switch transistor 640 is connected to a node 660 that is a first terminal of the holding capacitor C. A node 661 that is a second terminal of the holding capacitor C is connected to a potential line that supplies a predetermined potential. A control signal PFDINC is input to the gate of the switch transistor 640. Note that the control signal PFDINC may be input from the vertical scanning circuit 122.

The pixel circuit of the second modified example can connect the holding capacitor C to the FD 420 by turning on the switch transistor 640. Accordingly, it is possible to perform control to increase the capacitance value of the FD 420 in accordance with the control signal PFDINC to change the sensitivity of the pixel circuit.

The configuration of the pixel circuit may be a configuration other than the first modified example and the second modified example. For example, a circuit configuration that can control the reset potential VRES of the FD 420 by feeding back the output of the pixel circuit may be employed. When a capacitor element is used in such a circuit configuration, the MIM capacitor having the configuration illustrated in FIG. 8 is applicable to the capacitor element.

### Second Embodiment

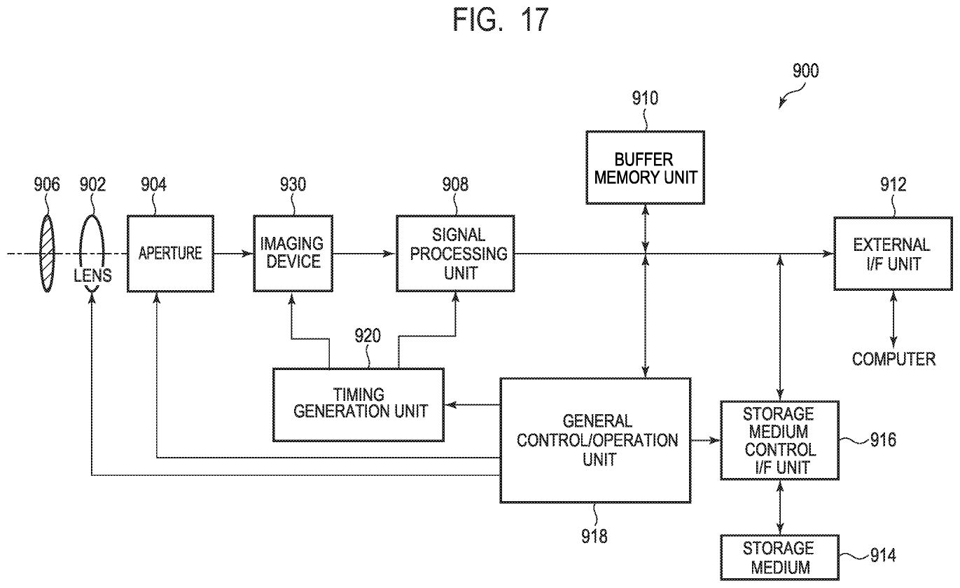

Next, an example of a device to which the imaging device according to the embodiment described above is applied will be described. FIG. 17 is a block diagram illustrating the configuration of an imaging system 900 according to the present embodiment. An imaging device 930 illustrated in FIG. 17 is the imaging device 100 described in the above first embodiment. The imaging system 900 to which the imaging device 100 is applicable may be, for example, a digital camera, a digital camcorder, a surveillance camera, or the like. FIG. 17 illustrates a configuration example of a digital camera to which the imaging device 100 described in the above embodiment is applied.

The imaging system 900 illustrated as an example in FIG. 17 has the imaging device 930, a lens 902 that captures an optical image of an object onto the imaging device 930, an aperture 904 for changing the amount of light passing through the lens 902, and a barrier 906 for protecting the lens 902. The lens 902 and the aperture 904 form an optical system that collects a light onto the imaging device 930.

The imaging system 900 further has a signal processing unit 908 that processes an output signal output from the imaging device 930. The signal processing unit 908 performs a signal processing operation to perform various correction and compression on an input signal, if necessary, and output the processed input signal.

The imaging system 900 further has a buffer memory unit 910 used for temporarily storing image data therein and an external interface unit (external OF unit) 912 used for communicating with an external computer or the like. The imaging system 900 further has a storage medium 914 such as a semiconductor memory used for performing storage or readout of imaging data and a storage medium control interface unit (storage medium control I/F unit) 916 used for performing storage or readout on the storage medium 914. Note that the storage medium 914 may be built in the imaging system 900 or may be removable.

The imaging system 900 further has a general control/operation unit 918 that controls various operations and the entire digital camera and a timing generation unit 920 that outputs various timing signals to the imaging device 930 and the signal processing unit 908. Here, the timing signal or the like may be externally input, and the imaging system 900 has at least the imaging device 930 and the signal processing unit 908 that processes an output signal output from the imaging device 930. The general control/operation unit 918 and the timing generation unit 920 may be configured to perform a part or the whole of the function regarding control of the photoelectric conversion device, such as generation of a control signal, generation of a reference voltage, or the like in the embodiment described above.

The imaging device 930 outputs an imaging signal to the signal processing unit 908. The signal processing unit 908 performs predetermined signal processing on an imaging signal output from the imaging device 930 and outputs image data. Further, the signal processing unit 908 uses an imaging signal to generate an image.

As discussed above, the imaging system 900 of the present embodiment includes the imaging device 930 according to the first embodiment. Accordingly, the imaging system 900 that enables higher quality image capturing can be realized.

### Third Embodiment

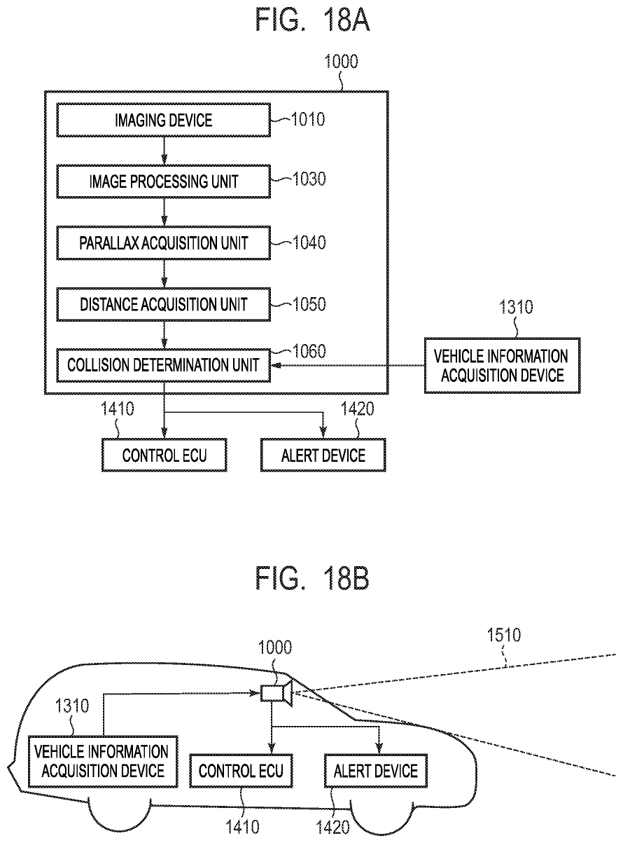

FIG. 18A and FIG. 18B are diagrams illustrating the configuration of an imaging system 1000 and a moving body according to the present embodiment. FIG. 18A illustrates one example of the imaging system 1000 related to an on-vehicle camera. The imaging system 1000 has the imaging device 100 described in the above first embodiment. An imaging device 1010 illustrated in FIG. 18A is the imaging device 100 described in the above first embodiment.

The imaging system 1000 has an image processing unit 1030 that performs image processing on a plurality of image data acquired by an imaging device 1010. Further, the imaging system 1000 has a parallax acquisition unit 1040 that calculates parallax information (a phase difference of parallax images) from the plurality of image data acquired by the imaging device 1010. Further, the imaging system 1000 has a distance acquisition unit 1050 that calculates a distance to the object based on the calculated parallax information and a collision determination unit 1060 that determines whether or not there is a collision possibility based on the calculated distance. Here, the parallax acquisition unit 1040 and the distance acquisition unit 1050 are an example of a distance information acquisition unit that acquires distance information on the distance to an object. That is, the distance information is information on a parallax, a defocus amount, a distance to an object, or the like. The collision determination unit 1060 may use any of the distance information to determine the collision possibility. The distance information acquisition unit may be implemented by dedicatedly designed hardware or may be implemented by a software module. Further, the distance information acquisition unit may be implemented by a field programmable gate array (FPGA), an application specific integrated circuit (ASIC), or the like or may be implemented by combination thereof. Note that the calculation of a parallax described above is performed by using signals read out from a plurality of electrodes within the imaging device 1010.

The imaging system 1000 is connected to the vehicle information acquisition device 1310 and can acquire vehicle information such as a vehicle speed, a yaw rate, a steering angle, or the like. Further, the imaging system 1000 is connected to a control ECU 1410, which is a control device that outputs a control signal for causing a vehicle to generate braking force based on a determination result by the collision determination unit 1060. That is, the control ECU 1410 is one example of a moving body control unit that controls the moving body based on the distance information. Further, the imaging system 1000 is also connected to an alert device 1420 that issues an alert to the driver based on a determination result by the collision determination unit 1060. For example, when the collision probability is high as the determination result of the collision determination unit 1060, the control ECU 1410 performs vehicle control to avoid a collision or reduce damage by applying a brake, pushing back an accelerator, suppressing engine power, or the like. The alert device 1420 alerts a user by sounding an alert such as a sound, displaying alert information on a display of a car navigation system or the like, providing vibration to a seat belt or a steering wheel, or the like.

In the present embodiment, an area around a vehicle, for example, a front area or a rear area is captured by using the imaging system 1000. FIG. 18B illustrates the imaging system 1000 when a front area of a vehicle (a capturing area 1510) is captured. The vehicle information acquisition device 1310 transmits an instruction to operate the imaging system 1000 to perform image capturing. The imaging system 1000 of the present embodiment including the imaging device 1010 according to the first embodiment can further improve the ranging accuracy.

Although the example of control for avoiding a collision to another vehicle has been described above, the embodiment is applicable to automatic driving control for following another vehicle, automatic driving control for not going out of a traffic lane, or the like. Furthermore, the imaging system is not limited to a vehicle such as the subject vehicle and can be applied to a moving body (moving apparatus) such as a ship, an airplane, or an industrial robot, for example. In addition, the imaging system can be widely applied to a device which utilizes object recognition, such as an intelligent transportation system (ITS), without being limited to moving bodies.

### OTHER EMBODIMENTS

Note that all the embodiments described above are mere embodied examples in implementing the present invention, and the technical scope of the present invention should not be construed in a limiting sense by these embodiments. That is, the present invention can be implemented in various forms without departing from the technical concept or the primary features thereof. For example, it should be understood that an embodiment in which a part of the configuration of any of the embodiments is added to another embodiment or an embodiment in which a part of the configuration of any of the embodiments is replaced with a part of the configuration of another embodiment is also one of the embodiments to which the present invention may be applied.

Note that, since the configuration of the first embodiment may be applied more generally to a photoelectric conversion device, the imaging systems of the second embodiment and the third embodiment described above can be expanded more generally to a photoelectric conversion system. That is, the device or the system to which the configuration of the first embodiment may be applied are not limited to an imaging system using an imaging device. For example, when a photoelectric conversion device is a ranging device, the photoelectric conversion system may be a ranging system.

Embodiments of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiments and/or that includes one or more circuits (e.g., application specific integrated circuit (ASIC)) for performing the functions of one or more of the above-described embodiments, and by a method performed by the computer of the system or apparatus by, for example, reading out and executing the computer executable instructions from the storage medium to perform the functions of one or more of the above-described embodiments and/or controlling the one or more circuits to perform the functions of one or more of the above-described embodiments. The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2019-078584, filed Apr. 17, 2019, which is hereby incorporated by reference herein in its entirety.

What is claimed is:

1. A photoelectric conversion device comprising:
a semiconductor substrate;
a photoelectric conversion layer;
a first electrode, a second electrode, and a third electrode each arranged between the photoelectric conversion layer and the semiconductor substrate; and
a fourth electrode arranged so as to face the first electrode, the second electrode, and the third electrode via the photoelectric conversion layer,
wherein the third electrode is arranged between the first electrode and the second electrode in a first direction parallel to the photoelectric conversion layer, wherein the third electrode is arranged apart from the first electrode by a first gap in the first direction,
wherein the third electrode is arranged apart from the second electrode by a second gap in the first direction,
wherein the first electrode, the second electrode, and the third electrode have a first length, a second length, and a third length, respectively, in the first direction, and wherein at least one of the first gap and the second gap is 0.8 times or more at least one of the first length, the second length, and the third length.

2. The photoelectric conversion device according to claim 1, wherein at least one of the first gap and the second gap is one time or more at least one of the first length, the second length, and the third length.

3. The photoelectric conversion device according to claim 1 further comprising a plurality of pixels each having the photoelectric conversion layer, the first electrode, the second electrode, the third electrode, and the fourth electrode,
wherein in a first pixel and a second pixel adjacent to each other out of the plurality of pixels, a gap between the first electrode, the second electrode, or the third electrode included in the first pixel and the first electrode, the second electrode, or the third electrode included in the second pixel is greater than or equal to the first gap and the second gap.

4. The photoelectric conversion device according to claim 1, wherein the third length is smaller than the first length or the second length.

5. The photoelectric conversion device according to claim 1,
wherein the first length is smaller than a fourth length of the first electrode in a second direction perpendicular to the first direction and parallel to the photoelectric conversion layer,
wherein the second length is smaller than a fifth length of the second electrode in the second direction, and
wherein the third length is smaller than a sixth length of the third electrode in the second direction.

6. The photoelectric conversion device according to claim 1, wherein the first electrode, the second electrode, and the third electrode are formed of a material that is nontransparent to an incident light.

7. The photoelectric conversion device according to claim 1 further comprising a metal insulator metal (MIM) capacitor arranged above the semiconductor substrate and below the first electrode, the second electrode, and the third electrode.

8. The photoelectric conversion device according to claim 7, wherein at least a part of the MIM capacitor overlaps a gap between the first electrode and the third electrode or a gap between the second electrode and the third electrode in plan view.

9. The photoelectric conversion device according to claim 7 further comprising:
a first conductive layer arranged below the first electrode, the second electrode, and the third electrode;
a second conductive layer arranged below the first conductive layer;
a third conductive layer arranged below the second conductive layer;
a first insulating layer arranged between the first conductive layer and the second conductive layer; and
a second insulating layer arranged between the second conductive layer and the third conductive layer,
wherein the MIM capacitor includes a portion in which the second conductive layer and the third conductive layer are overlapped via the second insulating layer in plan view.

10. The photoelectric conversion device according to claim 9, wherein a thickness of the second insulating layer is smaller than a thickness of the first insulating layer.

11. The photoelectric conversion device according to claim 9, wherein a thickness of the second insulating layer is less than or equal to 40 nm.

12. The photoelectric conversion device according to claim 9, wherein the first electrode, the second electrode, and the third electrode include a portion not overlapping the first conductive layer in plan view.

13. The photoelectric conversion device according to claim 9, wherein the third conductive layer is arranged so as to contain the second conductive layer in plan view.

14. The photoelectric conversion device according to claim 9 further comprising:
a fourth conductive layer arranged below the third conductive layer;
a fifth conductive layer arranged below the fourth conductive layer;
a third insulating layer arranged between the third conductive layer and the fourth conductive layer; and
a fourth insulating layer arranged between the fourth conductive layer and the fifth conductive layer,
wherein the MIM capacitor includes a portion in which the fourth conductive layer and the fifth conductive layer are overlapped via the fourth insulating layer in plan view.

15. The photoelectric conversion device according to claim 14, wherein a thickness of the fourth insulating layer is smaller than a thickness of the third insulating layer.

16. The photoelectric conversion device according to claim 14, wherein a thickness of the fourth insulating layer is less than or equal to 40 nm.

17. The photoelectric conversion device according to claim 14 further comprising:
a sixth conductive layer arranged below the fifth conductive layer;
a seventh conductive layer arranged below the sixth conductive layer;
a fifth insulating layer arranged between the fifth conductive layer and the sixth conductive layer; and
a sixth insulating layer arranged between the sixth conductive layer and the seventh conductive layer,
wherein the MIM capacitor includes a portion in which the sixth conductive layer and the seventh conductive layer are overlapped via the sixth insulating layer in plan view.

18. The photoelectric conversion device according to claim 17, wherein a thickness of the sixth insulating layer is smaller than a thickness of the fifth insulating layer.

19. The photoelectric conversion device according to claim 17, wherein a thickness of the sixth insulating layer is less than or equal to 40 nm.

20. The photoelectric conversion device according to claim 17, wherein a shape of at least one of the first conductive layer to the seventh conductive layer is different from a shape of at least another of the first conductive layer to the seventh conductive layer in plan view.

21. The photoelectric conversion device according to claim 7, wherein the MIM capacitor holds a signal read out from the first electrode, the second electrode, or the third electrode.

22. A photoelectric conversion system comprising:
the photoelectric conversion device according to claim 1; and
a signal processing unit configured to process a signal output from the photoelectric conversion device.

23. A moving body comprising:
the photoelectric conversion device according to claim 1;
a distance information acquisition unit configured to acquire distance information on a distance to an object, from parallax information based on signals from the photoelectric conversion device; and
a control unit configured to control the moving body based on the distance information.
